(19) United States
(12) Patent Application Publication
(10) Pub. No.: US 2014/0022727 A1
(43) Pub. Date: Jan. 23, 2014

(54) Cooling device for electronic components and control apparatus comprising the cooling device

(71) Applicant: Ezio Bertotto, Bolzano Vicentino (VI) (IT)

(72) Inventor: Ezio Bertotto, Bolzano Vicentino (VI) (IT)

(73) Assignee: REEL S.r.l., Ponte di Nanto (VI) (IT)

(21) Appl. No.: 13/990,034

(22) PCT Filed: Dec. 27, 2011
(86) PCT No.: PCT/IB2011/055970

§ 371 Date: Oct. 8, 2013

(30) Foreign Application Priority Data
Dec. 27, 2010 (IT) VI2010A000349

(51) Int. Cl. H05K 7/20

(52) U.S. Cl. CPC H05K 7/2089
USPC 361/689

(57) ABSTRACT

A cooling device for electronic components includes a substantially prismatic body made of a thermally conductive material, which has a pair of substantially planar main outer surfaces and encloses therein at least one circuit for the flow of a cooling fluid. Both main outer surfaces are designed to allow removable attachment of an electronic component to be cooled. A control apparatus incorporating the device.

### FIELD OF THE INVENTION

The present invention generally finds application in the field of cooling systems, and particularly relates to a cooling device for electronic components adapted for use in generator control apparatus.

The invention further relates to an electronic control apparatus for an electric generator or a similar machine.

### BACKGROUND ART

Electronic devices for common civil and industrial use are known to comprise one or more power components, which need to be cooled during operation to be maintained at a proper operating temperature.

Typically, the components to be cooled are thermally connected to one or more cooling devices, made of a high thermal-conductivity material, for intensive heat exchange with the surrounding environment.

These cooling devices are of lamellar type, which provide a considerable contact surface with the environment and afford high thermal efficiency.

One drawback of this solution is that electronic components often generate a large amount of heat, whose dissipation requires cooling devices of much larger sizes than the electronic device itself.

The dimensions of the apparatus that contains such electronic elements are dependent on the dimensions of the cooling devices, and the latter may be particularly large in control apparatus for wind, photovoltaic or the like generators, particularly with power outputs exceeding 400 kW.

In an attempt to at least partially obviate these drawbacks, electronic devices have been provided with forced circulation of a cooling fluid through the cooling devices.

Forced circulation of fluid between the lamellae of the cooling devices allows a larger amount of heat to be released therefrom to the fluid, and considerably increases the thermal efficiency of cooling devices.

This allows high heat-generating electronic components to be cooled by relatively small-sized cooling devices.

One drawback of this solution is that the electronic devices are required to have means for forced circulation of the cooling fluid, that have non negligible dimensions and power consumption.

Furthermore, the electronic device is often required to be held in closed compartments, such as cabinets or panels, in which circulation of the cooling fluid can be improved.

While this configuration allows the cooling devices to maintain a small size, it considerably increases the overall dimensions of the electronic device.

In order to improve cooling of the electronic components while maintaining their relatively small dimensions, plate-like cooling devices have been provided, which comprise an internal conduit for cooling fluid circulation.

IT1137472 discloses a cooling plate having two parallel flat faces, one of such faces being designed for attachment of the parts of the electronic circuit to be cooled.

The plate also encloses a closed-loop cooling circuit extending between its two ends, and having a cooling fluid, e.g. Freon therein.

One drawback of this prior art solution is that the cooling plate allows connection of the parts of the electronic device to be cooled to one of its flat faces only.

Furthermore, this solution does not allow connection of the cooling fluid with external cooling means, which can change its operating temperature and hence its efficiency.

### DISCLOSURE OF THE INVENTION

The object of the present invention is to overcome the above drawbacks, by providing a cooling device for electronic components that is highly efficient and relatively cost-effective.

A particular object is to provide a cooling device that can hold a large number of electronic components to be cooled.

A further particular object is to provide a cooling device for electronic components that can dissipate large amounts of heat while maintaining small dimensions.

Yet another object of the present invention is to provide a cooling device for electronic components that has particularly small dimensions, especially when used for cooling electronic apparatus designed to control high powers, e.g. exceeding 400 kW, in the field of renewable energy, such as wind, photovoltaic, hydraulic energy.

Another particular object is to provide a cooling device for electronic components that requires no circulation of an external cooling fluid during operation of the electronic component.

Yet another important particular object of the invention is to provide a cooling device for electronic devices that can be connected to means for cooling and pumping a cooling fluid.

These and other objects, as better explained below, are fulfilled by a cooling device for electronic components as defined in claim 1, which comprises a substantially prismatic body made of a thermally conductive material, said body having a pair of substantially planar main outer surfaces and enclosing therein at least one circuit for the flow of a cooling fluid.

The cooling device is characterized in that both main outer surfaces are adapted to removable secure at least one electronic component to be cooled.

This particular configuration will provide a cooling device for electronic components that has a particularly high thermal efficiency, while maintaining small overall dimensions and ensuring high durability and low maintenance requirements.

In a further aspect, the invention relates to an electronic control apparatus for an electric energy generator or a similar apparatus, as defined in claim 15, which comprises a cooling device of the invention.

Advantageous embodiments of the invention are defined in accordance with the dependent claims.

### BRIEF DESCRIPTION OF THE DRAWINGS

Further features and advantages of the invention will be more apparent from the detailed description of a preferred, non-exclusive embodiment of a cooling device for electronic components, which is described as a non-limiting example with the help of the annexed drawings, in which:

FIG. 1 is a front perspective view of a cooling device of the invention;

FIG. 2 is a rear perspective view of the device of FIG. 1;

FIG. 3 is a side view of the device of FIG. 1;

FIG. 4 is a front view of a first detail of the device of FIG. 1;

FIG. 5 is a front view of a second detail of the device of FIG. 1;

FIG. 6 is a sectional lateral view of the detail of FIG. 4, as taken along a plane VI-VI;

FIG. 7 is a sectional side view of the detail of FIG. 4, as taken along a plane VII-VII;

FIG. 8 is a front view of an electronic control device incorporating the cooling device of the invention;

FIG. 9 is a lateral view of the electronic control device of FIG. 8.

### DETAILED DESCRIPTION OF A PREFERRED EMBODIMENT

Referring to the above figures, the cooling device of the invention, generally designated by numeral 1, may be used in electronic devices D that use one or more electronic components C subject to heating.

The electronic components C may be either active semiconductor components, such as MOSFET, IGBT, or the like, or passive components, such as resistors and capacitors.

The cooling device 1 may be also used for cooling logic or storage portions of particularly complex electronic circuits and/or may be employed for cooling semiconductor integrated components.

Furthermore, the cooling device 1 may be used for cooling one or more electronic components C that are electrically interconnected by a PCB support.

The cooling device 1 of the invention comprises a substantially prismatic body 2, which is at least partially made of a thermally conductive material.

The body 2 has a pair of substantially planar main outer surfaces 3, 4 and encloses therein at least one circuit 5 for the flow of a cooling fluid F.

According to a peculiar feature of the invention, both main outer surfaces 3, 4 are designed to removably secure at least one electronic component C to be cooled.

In the configuration of the figures, the prismatic body 2 has a substantially rectangular plan shape, with a predetermined and substantially constant thickness s.

Advantageously, the cooling device 1 may be used in electronic apparatus operating at relatively high powers, e.g. exceeding 400 kW, because removable attachment of components to both main outer surfaces 3, 4 allows the apparatus to have considerably smaller dimensions than prior art apparatus.

For example, according to an exemplary, non-limiting aspect of the present invention, the cooling device may be used in inverters and converters for electric generators producing high power output from renewable energy sources, such as wind, photovoltaic, hydraulic or the like generators.

The body 2 may be made of a base material selected from the group of high thermal conductivity materials, such as copper, aluminum and alloys thereof.

Conveniently, the cooling fluid F may be any liquid or gaseous fluid adapted for use in cooling or refrigeration circuits and may also be water or a water-based refrigerant.

Both main outer surfaces 3, 4 may be designed for securing one or more electronic components C to be cooled, so that a thermal contact is created, extending over at least a portion U of their surface S, which is designed to be connected with external cooling devices 1.

Furthermore, each of the main outer surfaces 3, 4 may be designed for attachment of electronic components C of different sizes and different fastening systems.

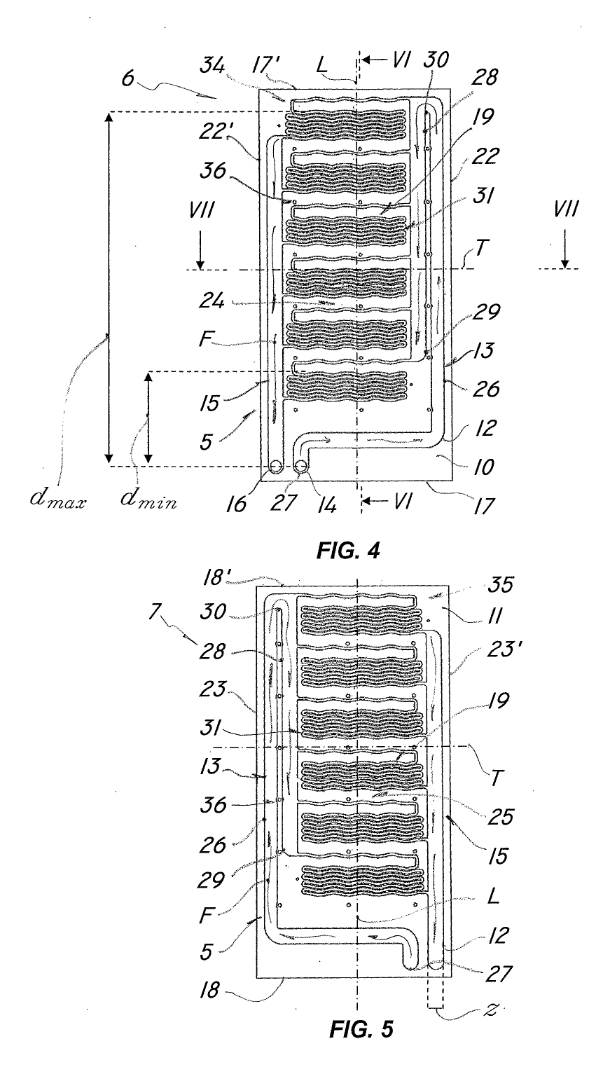

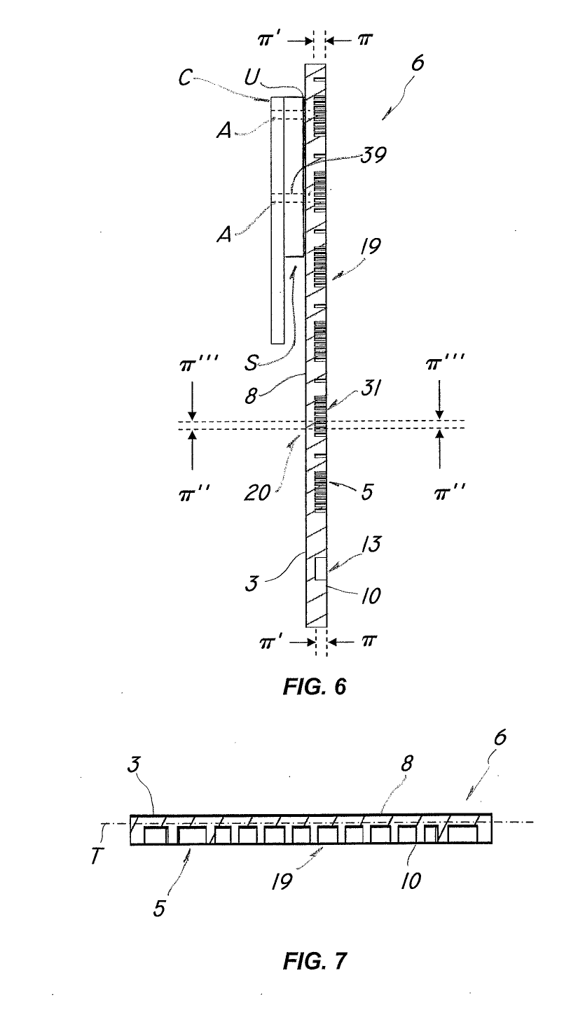

Advantageously, the prismatic body 2 may comprise a pair of substantially specular mutually facing half shells 6, 7, as shown in FIG. 4 and FIG. 5 respectively, which define the main outer surfaces 3, 4 by their respective outer faces 8, 9.

Each half shell 6, 7 may substantially have a plate shape, with a constant thickness s₁, s₂ equal to half the thickness s of the prismatic body 2.

Particularly, in the configuration of the figures, the half-shells 6, 7 have equal thicknesses s₁, s₂ and substantially coincident plan sizes.

Nevertheless, it shall be understood that, in alternative configurations, not shown, the half-shells 6, 7 may have one or more considerably different dimensions, such as the thickness s₁, s₂, which may also not be constant.

Conveniently, the main outer surfaces 3, 4 are substantially parallel.

Furthermore, the half-shells 6, 7 have inner surfaces 10, 11, which are designed to be mutually coupled along a coupling middle plane π.

As shown again in FIGS. 4 and 5, the inner surface 10, 11 of each half shell 6, 7 may be substantially planar and parallel to the corresponding main outer surface 3, 4.

In this configuration, when the half shells 6, 7 are mutually coupled, the coupling middle plane IF is substantially parallel to the main outer surfaces 3, 4.

Furthermore, the circuit 5 may comprise a duct 12 with a feeding section 13 connected to an inlet port 14 and a discharge section 15 connected to an outlet port 16.

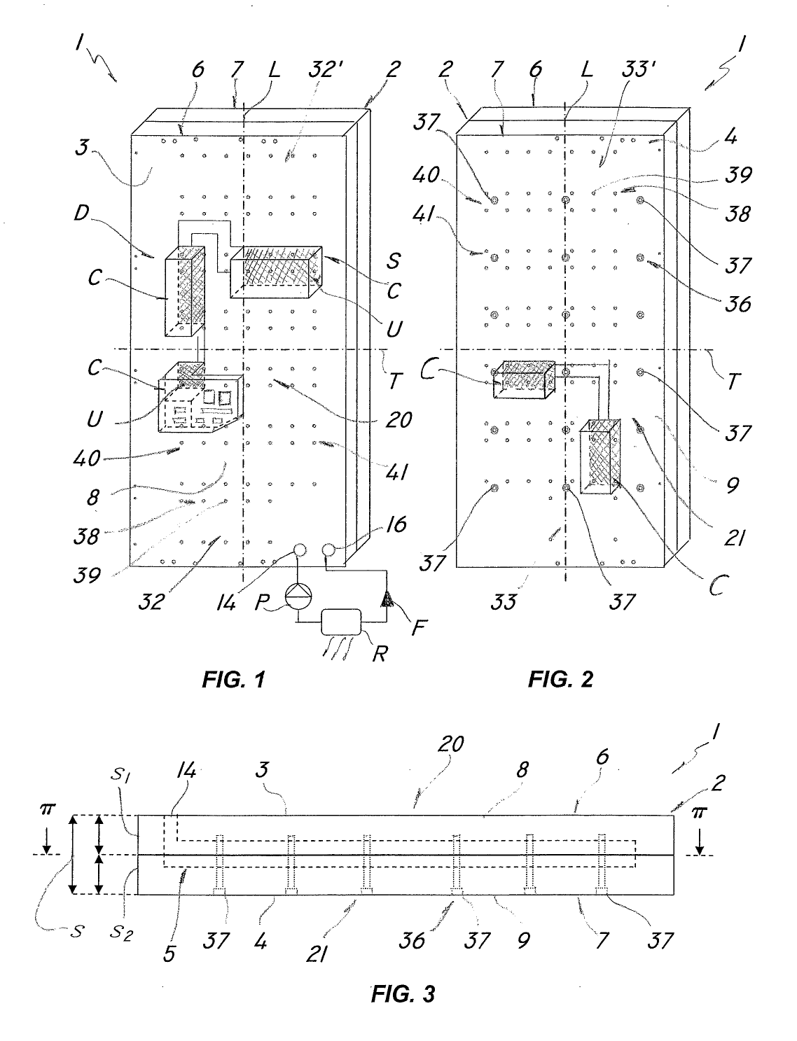

Advantageously, as shown in FIGS. 1 and 4, the inlet port 14 and the outlet port 16 may be formed in the same half shell 6, 7.

Particularly, the inlet port 14 and the outlet port 16 for the fluid F may be located in the proximity of a first end edge 17, 18 of one of the half shells 6, 7.

The duct 12 may have a substantially constant section z, which will determine the flow of cooling fluid F through the device 1.

Furthermore, the inlet port 14 and the outlet port 16 may be in fluid connection with a circuit for pumping P and cooling R the fluid F.

The pumping P and cooling R circuit may be designed to change the flow rate and temperature of the fluid F fed to the inlet port 14 of the device 1.

In a particularly advantageous embodiment of the invention, as shown in FIGS. 4 and 5, the duct 12 may include one or more serpentine sections, generally referenced 19, interposed between the feeding section 13 and the discharge section 15.

A predetermined number of serpentine sections 19 may be provided, to create a thermal connection of the duct 12 with a predetermined portion 20, 21 of the main outer surfaces 3, 4 of the prismatic body 2.

For example, the duct 12 may extend substantially all along the main outer surfaces 3, 4.

Conveniently, the feeding sections 13 and the discharge sections 15 are substantially parallel in a longitudinal direction L.

Also, a plurality of serpentine sections 19 are provided, extending transverse to the longitudinal feeding 13 and discharge 15 sections and connected thereto in parallel.

The feeding 13 and discharge 15 sections are located in the proximity of the opposite longitudinal end edges 22, 22′; 23, 23′ of the half shells 6, 7 and each serpentine section 19 extends in a central portion 24, thereof.

Advantageously, the serpentine sections 19 are mutually longitudinally offset and the feeding section 13 may be designed to sequentially feed the serpentine portions 19 starting from the one located at the maximum longitudinal distance dₘₐₓ from the inlet port 14.

The feeding section 13 so configured can feed all the serpentine sections 19 with the fluid F at minimum temperature flowing in from the inlet port 14 at substantially coincident times.

Simultaneous feeding of the serpentine sections 19 with the minimum temperature fluid F will allow the latter to maintain heat exchange substantially constant throughout the portion 20, 21 of the main surface 3, 4 covered by the serpentine section 19, so that a substantially uniform temperature can be maintained thereon.

According to the configuration of the figures, the half shells 6, 7 include six serpentine sections 19 interposed between the feeding section 13 and the discharge section 15, arranged on a column in equally spaced relation.

In other configurations of the invention, not shown, the cooling coil sections 19 may be in greater and smaller numbers than those in the figures, and may be arranged out of alignment with each other, at different distances from each other.

The feeding section 13 has a first longitudinal portion 26 having the inlet port 14 at one end 27, and a second longitudinal portion 28 having one end 29 connected to the serpentine section 19 located at the minimum distance dₘᵢₙ from the inlet port 14 for the fluid F.

Furthermore, the first longitudinal portion 26 of the feeding section 13 has a second end 30 in fluid connection with the second portion 28 and to the serpentine section 19 located at the maximum longitudinal distance dₘₐₓ from the inlet port 14.

The second portion 28 is designed to feed all the serpentine sections 19 connected thereto at substantially coincident times, to ensure the same thermal efficiency throughout the portion 20, 21 of the main outer surface 3, 4 covered by the circuit 5.

Furthermore, each of the serpentine sections 19 may comprise a plurality of substantially parallel channels, generally referenced 31, having a waved path.

The waved path may extend on a plane π′ substantially parallel to the middle plane π and to a substantially transverse axis T.

In the configuration of the invention as shown, each serpentine section 19 has wave paths of identical longitudinal extension.

However, in one embodiment, not shown, each serpentine section 19 may have wave paths with different longitudinal extensions to provide a different heat exchange in predetermined separate portions 32, 32′; 33, 33′ of the main outer surfaces 3, 4.

Advantageously, the waved profile of the serpentine sections 19 may also extend on planes π″, π′″ substantially perpendicular to the coupling middle plane π and on each side thereof.

Such configuration, not shown, can increase the thermal efficiency of the device 1 by providing a different distribution of fluid F along the thickness s of the prismatic body 2.

In a further particularly advantageous aspect of the invention, a mirror-like half 34, 35 of the cooling circuit 5 is formed on each of the inner surfaces 10, 11 of the half shells 6, 7.

This will allow the cooling circuit 5 to be formed by coupling together the mirror-like inner surfaces 10, 11 of the half shells 6, 7.

In one configuration of the invention, not shown, the circuit 5 on each half shell 6, 7 may also be more or less than one half.

Conveniently, each mirror-like half 34, 35 of the circuit 5 is formed in its respective half shell 6, 7 and is adapted to hermetically join to the other specular half 35, 34 by appropriate connecting means 36.

As shown in FIGS. 2, 3 and 4, the connecting means 36 may include screw means 37 evenly arranged over the main outer surface 3, 4 of the half shell 6, 7 that has no inlet port 14 and outlet port 16 for the fluid F.

Furthermore, the half shells 6, 7 may be mechanically joined together, e.g. by welding or brazing along the transverse end edges 17, 17′; 18, 18′ and the longitudinal edges 22, 22′; 23, 23′ of their inner surfaces 10, 11.

Conveniently, each mirror-like half 34, 35 of the circuit 5 may be formed by a mechanical working process on its respective half-shell 6, 7, selected from mechanical machining, molding or the like.

Also, the circuit 5 may be also formed by the combination of one or more mechanical machining processes, for example a rough molding process and a finishing process by material removal.

In a particularly advantageous aspect of the invention, the device 1 may comprise anchoring means 38, generally referenced 38, for attachment of electronic components C, which may be of screw type or similar, on both main outer surfaces 3, 4 of the half-shells 6, 7.

Conveniently, as shown, the anchor means 28 may comprise one or more threaded anchor holes, generally referenced 39, for removable connection of the electronic component C.

In other configurations of the invention, not shown, the anchoring means 38 may be other than screw means, and may be for instance snap fit means, interlock means, or the like.

The anchoring means 38 may include a plurality of series, generally referenced 40, of anchor holes 39, each of such series 40 comprising at least one transverse row, generally referenced 41, of holes 40 at a respective serpentine portion 19.

Thus, the electronic components C to be cooled may be anchored to the main outer surface 3, 4 in the positions where the maximum thermal efficiency of the device 1 can be obtained.

The holes 39 are designed to be aligned with corresponding holes A of the electronic component C to be anchored for mutual fastening by screws or the like.

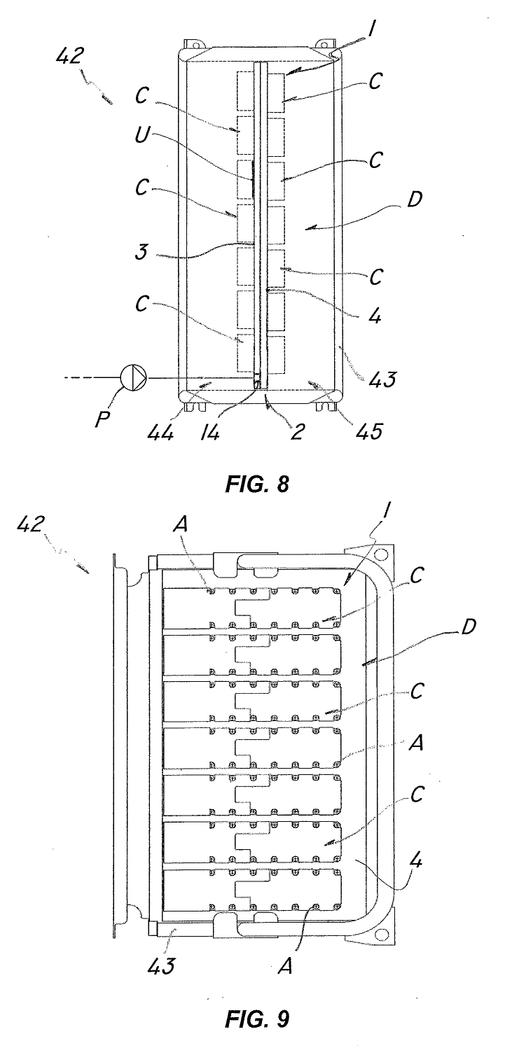

In a further aspect, as shown in FIGS. 8 and 9, the invention relates to an electronic control device 42 for an electric generator, not shown, or a similar apparatus, comprising one or more electronic components C electrically connected to control a generator or a similar apparatus.

Furthermore, the electronic control device 42 incorporates a cooling device 1 for the electronic components C as described above.

The electronic control device may comprise a box-like support frame 43 containing one or more electrically interconnected electronic components C.

As shown in FIG. 8, the cooling device 1 may be connected to the interior of the frame 43 to define two inner compartments 44, 45 for receiving any electrically connected electronic devices D that do not require heat dissipation.

Conveniently, the cooling device 1 may be connected to the interior of the box-like frame 44 in such a manner that the inlet port 14 and the outlet port 16 for the fluid F may be oriented to facilitate connection with the external fluid pumping means P.

Such a configuration of the electronic control device 42 allows dissipation of a large amount of heat generated by one or more electronic components C, while maintaining a relatively small size of the device.

The cooling device and electronic control device of the invention are susceptible to a number of changes and variants, within the inventive concept disclosed in the appended claims. All the details thereof may be replaced by other technically equivalent parts, and the materials may vary depending on different needs, without departure from the scope of the invention.

While the cooling device and electronic control device have been described with particular reference to the accompanying figures, the numerals referred to in the disclosure and claims are only used for the sake of a better intelligibility of the invention and shall not be intended to limit the claimed scope in any manner.

The invention claimed is:

1. A cooling device (1) for electronic components (C), comprising:
a substantially prismatic body (2) made of a thermally conductive material, said body (2) having a pair of outer main surfaces (3, 4) substantially planar and enclosing internally thereof at least one circuit (5) for the flow of a cooling fluid (F),
wherein both of said outer main surfaces (3, 4) are adapted to removably secure at least one electronic component (C) to be cooled.

2. The device as claimed in claim 1, wherein said prismatic body (2) comprises a pair of substantially mirror-like and reciprocally facing half-shells (6, 7) defining with respective outer faces (8, 9) said outer main surfaces (3, 4).

3. The device as claimed in claim 2, wherein said main outer surfaces (3, 4) are substantially parallel, said half-shells (6, 7) having inner faces (10, 11) designed to be reciprocally coupled along a middle coupling plane (π).

4. The device as claimed in claim 2, wherein said circuit (5) comprises a duct (12) with a feeding section (13) connected to one inlet port (14) and a discharge section (15) connected to one outlet port (16), said inlet port (14) and said outlet port (16) being formed in only one of said half-shells (6, 7).

5. The device as claimed in claim 4, wherein said duct (12) further comprises one or more cooling serpentine sections (19) interposed between said feeding section (13) and said discharge section (15).

6. The device as claimed in claim 5, wherein said feeding (13) and discharge (15) sections are substantially mutually parallel along a longitudinal direction (L), a plurality of cooling serpentine sections (19) being provided which extend transversely to said longitudinal feeding (13) and discharge (15) sections and parallel connected therewith.

7. The device as claimed in claim 6, wherein said cooling serpentine sections (19) are reciprocally longitudinally offset, said feeding sections (13) being configured to sequentially feed said cooling serpentine sections (19) starting from that serpentine section located at a maximum longitudinal distance (dₘₐₓ) from said inlet port (14).

8. The device as claimed in claim 6, wherein said main outer surfaces (3, 4) are substantially parallel, said half-shells (6, 7) having inner faces (10, 11) designed to be reciprocally coupled along a middle coupling plane (π), and wherein each of said cooling serpentine sections (19) comprises a plurality of substantially parallel channels (31) having a waved path, with waves extending on a plane (π′) substantially parallel to said coupling middle plane (π) and respect to a substantially transverse axis (T).

9. The device as claimed in claim 8, wherein said waved path of said cooling serpentine sections (19) also extends on planes (π″, π′″, . . . ) substantially perpendicular to said coupling middle plane (π) and on opposite sides thereof.

10. The device as claimed in claim 3, wherein a mirror-like half (34, 35) of said at least one circuit (5) is formed in each of said inner faces (10, 11).

11. The device as claimed in claim 10, wherein said mirror-like half (34, 35) of said circuit (5) is hermetically joined to another mirror-like half (35, 36).

12. The device as claimed in claim 10, wherein each mirror-like half (34, 35) of said circuit (5) is formed by mechanical working of a respective half-shell (6,7).

13. The device as claimed in claim 2, wherein electronic components (C) are anchored on one or both of both of said outer main surfaces (3, 4) of said half-shells (6, 7).

14. The device as claimed in claim 1, wherein a base material of said prismatic body (2) is selected from the group consisting of copper, aluminium, and their alloys.

15. An electronic apparatus (42) for controlling an electric energy generator or similar machine, comprising:
one or more electronic components (C) electrically mutually connected for controlling a generator or a similar machine; and
a cooling device (1) for cooling said one or more electronic components (C),
wherein said cooling device (1) comprises a prismatic body (2) as claimed in claim 1, said cooling device (1) enclosing internally thereof at least one circuit (5) for a flow of a cooling fluid (F) and being adapted to receive said one or more electronic components (C) on both its outer main surfaces (3, 4).
